(19) United States
(12) Patent Application Publication
(10) Pub. No.: US 2023/0217630 A1
(43) Pub. Date: Jul. 6, 2023

(54) APPARATUS AND SYSTEM FOR TWO-PHASE SERVER COOLING WITH SERIAL CONDENSER UNITS

(71) Applicant: Baidu USA LLC, Sunnyvale, CA (US)

(72) Inventor: Tianyi GAO, San Jose, CA (US)

(21) Appl. No.: 17/565,749

(22) Filed: Dec. 30, 2021

(51) Int. Cl. H05K 7/20

(52) U.S. Cl. CPC H05K 7/203; H05K 7/20318; H05K 7/20327; H05K 7/20809

(57) ABSTRACT

Embodiments are disclosed of an information technology (IT) cooling system. The system includes an IT container having an internal volume. Inside the internal volume there is an immersion fluid region adapted to submerge one or more servers in a two-phase immersion fluid. An immersion condenser is positioned above the immersion fluid region in the internal volume. The design includes a circulation condenser. The circulation condenser is fluidly coupled to a liquid distribution manifold and a vapor return manifold that are positioned in the internal volume above the immersion tank (i.e., the immersion fluid region) and are adapted to circulate a two-phase circulation fluid. The circulation condenser is also fluidly coupled to the immersion condenser, and an external cooling fluid is pumped from the circulation condenser to the immersion condenser. The distribution manifolds are adapted to be fluidly coupled to the server liquid cooling loops.

### TECHNICAL FIELD

The disclosed embodiments relate generally to information technology (IT) liquid cooling systems, but not exclusively, to an apparatus and system for two-phase server cooling using serial condenser units.

### BACKGROUND

Modern data centers like cloud computing centers house enormous amounts of information technology (IT) equipment such as servers, blade servers, routers, edge servers, power supply units (PSUs), battery backup units (BBUs), etc. These individual pieces of IT equipment are typically housed in racks within the computing center, with multiple pieces of IT equipment in each rack. The racks are typically grouped into clusters within the data center.

As IT equipment has become more computationally powerful it also consumes more electricity and, as a result, generates more heat. This heat must be removed from the IT equipment to keep it operating properly. Various cooling solutions have been developed to keep up with this increasing need for heat removal. One of the solutions is immersion cooling, and which the IT equipment is itself submerged in a cooling fluid. The cooling fluid can be a single-phase or two-phase cooling fluid; in either case, heat from the IT equipment is transferred into the cooling fluid in which it is submerged. But existing two-phase immersion cooling systems have the coolant only within the IT enclosure, and current two-phase immersion cooling solutions do not sufficiently support high power density servers which include one or more high power-density chips. Such designs are inefficient and may not be a proper solution for hyperscale deployment.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 is a schematic view of an embodiment of an information technology (IT) cooling system.

FIG. 2 is a schematic view of another embodiment of an IT cooling system.

FIG. 3 is a schematic view of another embodiment of an IT cooling system.

FIG. 4 is a schematic view of another embodiment of an IT cooling system.

### DETAILED DESCRIPTION

Embodiments are described of a two-phase cooling system for use with information technology (IT) equipment in a data center or an IT container such as an IT rack. Specific details are described to provide an understanding of the embodiments, but one skilled in the relevant art will recognize that the invention can be practiced without one or more of the described details or with other methods, components, materials, etc. In some instances, well-known structures, materials, or operations are not shown or described in detail but are nonetheless encompassed within the scope of the invention.

Reference throughout this specification to “one embodiment” or “an embodiment” means that a described feature, structure, or characteristic can be included in at least one described embodiment, so that appearances of “in one embodiment” or “in an embodiment” do not necessarily all refer to the same embodiment. Furthermore, the particular features, structures, or characteristics may be combined in any suitable manner in one or more embodiments. As used in this application, directional terms such as “front,” “rear,” “top,” “bottom,” “side,” “lateral,” “longitudinal,”etc., refer to the orientations of embodiments as they are presented in the drawings, but any directional term should not be interpreted to imply or require a particular orientation of the described embodiments when in actual use.

The disclosed embodiments are systems for two-phase cooling of IT components. The disclosed embodiments use more than one type of two-phase immersion coolant for solving challenges related to high power thermal management and corresponding challenges associated with two-phase immersion cooling technologies. In addition, the disclosed embodiments enable some or all of the following benefits:
Accommodate different IT enclosures and different deployment scales.
Different data center architectures, both brownfield and greenfield.
Scalable for different power densities.
High efficiency.
Efficient and accurate control.
Accommodate different redundant requirements.
Ease of design and implementation.
Enable designing system with at least two types of immersion coolant with different boiling temperatures.
More advanced two-phase thermal fluid management.

The described embodiments are cooling systems that use two or more two-phase cooling fluids with different boiling temperature to extract the heat load from high power density components more efficiently and solve challenges in designing cooling systems using two-phase coolants.

The described embodiments include a pair of two-phase cooling loops. The first two-phase cooling loop is a two-phase immersion system in which all the servers and electronics are submerged in the liquid phase of a two-phase immersion fluid. The vapor phase of the immersion coolant is cooled by an immersion condenser. The second two-phase cooling loop uses a two-phase circulation fluid different from the two-phase immersion fluid. The liquid phase of the circulation fluid is circulated through cooling devices thermally coupled to heat loads, where it is converted to the vapor phase. The resulting vapor phase is cooled by a circulation condenser. The immersion condenser and the circulation condenser are connected in series in one cooling fluid loop. In one embodiment the two-phase circulation loop is a pumped two-phase loop, but in other embodiments, the two-phase circulation loop uses gravity to drive flow of the liquid phase.

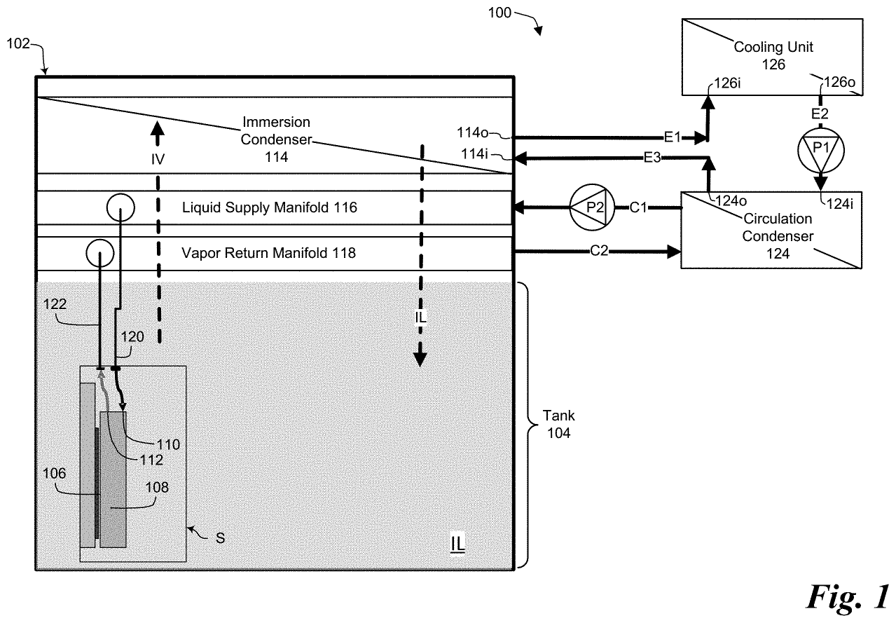

FIG. 1 illustrates an embodiment of an information technology (IT) cooling system 100. Cooling system 100 combines immersion cooling with local fluid circulation to cool heat-generating electronics components. Immersion cooling is accomplished with a two-phase immersion fluid I having a liquid phase IL and a vapor phase IV, while circulation cooling is accomplished with a two-phase circulation fluid C having a liquid phase CL and a vapor phase CV. In most embodiments immersion cooling fluid I will be a dielectric fluid, meaning that it has little or no electrical conductivity. In one embodiment, immersion cooling fluid I and circulation cooling fluid C are different two-phase fluids; depending on the application, in various embodiments immersion cooling fluid I and circulation cooling fluid C will have different boiling points. In an embodiment where circulation fluid C must extract more heat than immersion fluid I, circulation fluid C will have a lower boiling point, enabling it to absorb and transfer away more heat. A third cooling fluid, external cooling fluid E, can be used to improve or speed up the transition from vapor phase to liquid phase for both two-phase cooling fluids I and C. The system is designed to minimize or prevent mixing of the immersion (I), circulation (C), and external (E) fluids.

Cooling system 100 includes an information technology (IT) container 102 that defines an internal volume. An immersion tank 104 in the internal volume is adapted to hold the liquid phase IL of two-phase immersion cooling fluid I. In the illustrated embodiment immersion tank 104 is part of the IT container and is formed by a lower portion of the internal volume of IT container 202, but in other embodiments immersion tank 104 can be a physically separate tank within IT container 102. IT container 102 is sealed to reduce or prevent escape of liquid phase IL and, during operation, escape of vapor phase IV. Immersion tank 104 can be understood as the immersion fluid region in this design—that is, the region in which servers are immersed and submerged in two-phase immersion fluid I for cooling, as further described below.

In the illustrated embodiment, one or more servers S are within the IT container 102. The illustrated embodiment includes one server S, but other embodiments can have more servers than shown. Within each server S there are one or more heat-generating electronic components 106, and a cooling device 108 is thermally coupled to the heat-generating electronic component. Cooling device 108, which can be an evaporator in one embodiment, has a liquid inlet 110 and a vapor outlet 112. Server S is submerged in liquid phase IL, and to ensure immersion cooling of the server the amount or level of liquid phase IL in immersion tank 104 is set so that the one or more servers S always remain fully submerged in the liquid phase.

Besides immersion tank 104, three main components are positioned above immersion tank 104 in the interior volume of IT container 102: an immersion condenser 114, a liquid supply manifold 116, and a vapor return manifold 118. Immersion condenser 114 is not coupled by physical fluid connections to other components within IT container 102. Liquid supply manifold 116 is fluidly coupled by a liquid line 120 to inlet 110 of cooling device 108, and vapor return manifold 118 is fluidly coupled by a vapor return line 122 to vapor outlet 112. As described below, cooling device 108, liquid supply manifold 116 and vapor return manifold 118 form part of a two-phase circulation cooling loop to provide localized two-phase cooling to heat-generating component 106.

Several external components outside IT container 102 are fluidly coupled to the components within IT container 102 to assist them in performing their functions. A circulation condenser 124 is fluidly coupled to liquid supply manifold 116 by a liquid supply line C1 and is fluidly coupled to vapor return manifold 118 by vapor return line C2, so that liquid phase CL flows through C1 and vapor phase CV flows through C2. A pump P2 is fluidly coupled into liquid supply line C1 to boost the pressure and/or flow rate of liquid phase CL flowing into and through liquid supply manifold 116.

A cooling unit 126 is fluidly coupled to both immersion condenser 114 and circulation condenser 124. Cooling unit 126 circulates external cooling fluid E through both condensers, improving their ability to condense their respective two-phase fluids. To circulate external cooling fluid E through both condensers, an external outlet 114o of immersion condenser 114 is fluidly coupled by fluid line E1 to inlet 126 of cooling unit 126 and an external outlet 126o of cooling unit 126 is fluidly coupled by fluid line E2 to an external inlet 124i of circulation condenser 124. A pump P1 is coupled into fluid line E2 to boost the flow of external cooling fluid E into circulation condenser 124. Finally, an external outlet 124o of circulation condenser 124 is then coupled by fluid line E3 to an external inlet 114i of immersion condenser 114. In respect of the loop of cooling fluid E, the circulation condenser and immersion condenser are in series. In other embodiments pump P1 can instead be coupled into fluid line E3 or fluid line E1.

During operation of cooling system 100, heat-generating components within servers S are cooled by both the immersion cooling loop and the circulation cooling loop. In the immersion cooling loop, heat generated by heat-generating components 106 within servers S is transferred to liquid phase IL of the immersion fluid I, transforming it by evaporation into vapor phase IV. Vapor phase IV rises into the space between a surface of the liquid phase IL in immersion tank 104 and the top of IT container 202, where it enters immersion condenser 114 and condenses back into liquid phase IL. External cooling E from cooling unit 126 flows in and out of immersion condenser 114, as described above, to improve the condensation rate of immersion condenser 114. Under the force of gravity, liquid phase IL drops from immersion condenser 114 back into immersion tank 104, where it will again be transformed by heat from component into vapor phase IV, thus completing the immersion cooling loop.

The circulation cooling loop operates simultaneously with the immersion cooling loop to provide enhanced and more localized cooling to heat-generating components 106. The liquid phase CL of circulation cooling fluid C flows from liquid supply manifold 116, through liquid supply line 120 and liquid inlet 110, into cooling device 108, where the liquid phase CL absorbs heat from heat-generating device 106 and is converted into vapor phase CV. Vapor phase CV then flows out of cooling device 108 through vapor outlet 112 and vapor line 122 to vapor return manifold 118. Vapor phase CV then flows from vapor return manifold 118 into circulation condenser 124 through vapor line C2. In circulation condenser 124, vapor phase CV, with the help of external cooling fluid E from cooling unit 126, condenses vapor phase CV back into liquid phase CL. Liquid phase CL is then returned through liquid supply line C1, with the assistance of pump P2, from the circulation condenser to liquid supply manifold 116, thus completing the circulation cooling loop. The immersion cooling loop and the circulation cooling loop are fully separated and operate independently without mixing their respective two-phase fluids. In system 100 the circulation loop is the main cooling system because it functions as a localized high power density thermal management system in a fully two-phase immersion environment. For this reason, external cooling fluid E is first delivered to the circulation condenser through fluid line E2 before being delivered to the immersion condenser through fluid line E3.

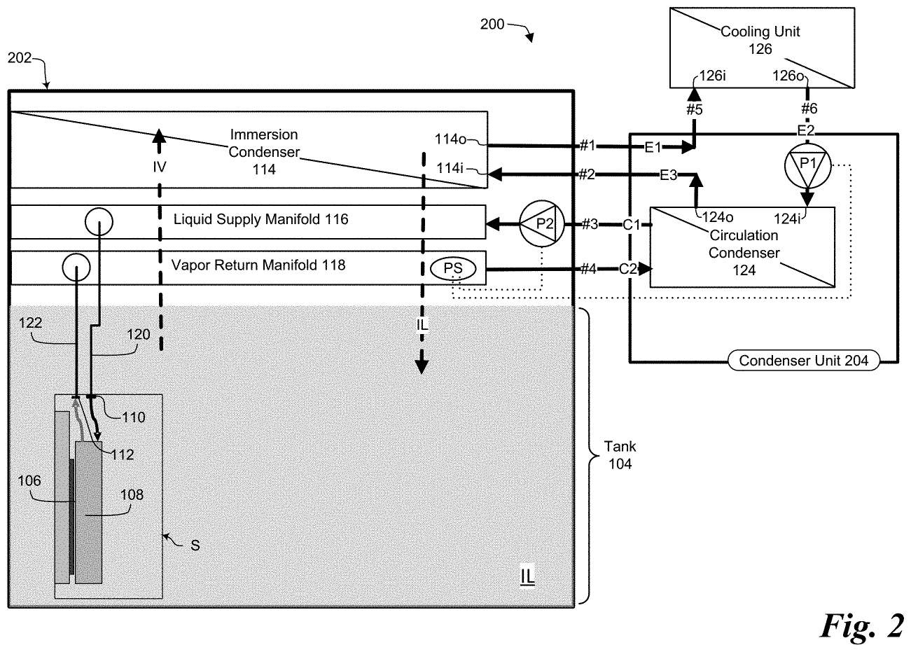

FIG. 2 illustrates an embodiment of an information technology (IT) cooling system 200. Cooling system 200 is in most respects similar to cooling system 100. The primary difference between cooling systems 100 and 200 is that in cooling system 200 the elements are grouped and packaged differently so that the system can be modularized.

In system 200, IT container 202 has an internal volume, and all the same elements within the internal volume of IT container 102 are also found within IT container 202: immersion tank 104, server S, immersion condenser 114, liquid supply manifold 116 and vapor return manifold 118. All of these components are positioned the same way, and have the same fluid connections among themselves, as they do in IT container 102. But unlike IT container 102, IT container 202 has pump P2 positioned in the internal volume rather than outside the IT container.

In system 200, the elements outside the IT container—principally circulation condenser 124 and cooling unit 126—are grouped and packaged differently than in system 100. Cooling unit 126 remains a separate unit, but circulation condenser 124, pump P1, and parts of the fluid lines between elements are grouped together and packaged in a condenser unit 204. In the illustrated embodiment, parts of fluid lines E1, E2, and E3 are grouped and packaged within condenser unit 204.

The fluid connections between cooling unit 126 and circulation condenser 124 and pump P1 in condenser unit 204, and the fluid connections between cooling unit 126 and elements within IT container 202, remain substantially the same as in system 100. Circulation condenser 124 is fluidly coupled to liquid supply manifold 116 by a liquid supply line C1 and is fluidly coupled to vapor return manifold 118 by vapor return line C2, with liquid phase CL flowing through C1 and vapor phase CV flowing through C2. Pump P2 is fluidly coupled into liquid supply line C1 to boost the pressure and/or flow rate of liquid phase fluid CL flowing into and through liquid supply manifold 116. To circulate external cooling fluid E through both condensers, an external outlet 114o of immersion condenser 114 is fluidly coupled by fluid line E1 to inlet 126 is of cooling unit 126; an external outlet 126o of cooling unit 126 is fluidly coupled by fluid line E2 to an external inlet 124i of circulation condenser 124. A pump P1 is coupled into fluid line E2 to boost the flow of external cooling fluid E into circulation condenser 124. An external outlet 124o of circulation condenser 124 is then coupled to an external inlet 114i of immersion condenser 114.

To support the modularization of components in system 200, some or all of IT container 202, condenser unit 204, and cooling unit 126 include fluid interfaces to allow one unit to be fluidly coupled to another quickly and efficiently. System 200 includes six fluid interfaces, but other embodiments can include more or less fluid interfaces than shown. In system 200, fluid interfaces #1 through #4 couple elements within condenser unit 204 to elements within IT container 202, while fluid interfaces #5 and #6 couple elements within condenser unit 204 to cooling unit 126. The fluid interfaces are as follows:
Fluid interfaces #1 and #5 are both fluidly coupled in fluid line E1 between external outlet 114o of immersion condenser unit 114 and external inlet 126i of the cooling unit. Fluid interface #1 is positioned in fluid line E1 between IT container 202 and condenser unit 204, while fluid interface #5 is positioned in fluid line E1 between condenser unit 204 and the inlet 126i of the cooling unit.
Fluid interface #2 is fluidly coupled in fluid line E3 between external outlet 124o of circulation condenser 124 and external inlet 114i of immersion condenser 114. Fluid interface #2 is positioned in line E3 between condenser unit 204 and IT container 202.
Fluid interface #3 is fluidly coupled in fluid line C1 between circulation condenser 124 and pump P2 and liquid supply manifold 116. Fluid interface #3 is positioned in line C1 between condenser unit 204 and IT container 202.
Fluid interface #4 is fluidly coupled in fluid line C2 between vapor return manifold 118 and circulation condenser 124. Fluid interface #4 is positioned in line C2 between condenser unit 204 and IT container 202.

In one embodiment the fluid interfaces can be quick connect/disconnect fluid connectors, but in other embodiments the fluid interfaces can be another type of fluid connector such as a blind mating connector. In one embodiment all the fluid interfaces can be of the same type, but in other embodiments they need not all be of the same type. And although they are individually referred to in the singular as a fluid interface, each fluid interface can include one or more fluid connectors. For instance, in one embodiment fluid interfaces #3 and #4 can include a single connector between the IT container 202 and condenser unit 204, but in another embodiment these same fluid interfaces can include multiple fluid connectors—e.g., one fluid connector at IT container 202 and another at condenser unit 204.

System 200 operates in substantially the same way as described above for system 100, with the addition of some controls. System 200 includes a pressure sensor PS that is positioned in vapor return manifold 118 and is communicatively coupled to pumps P1 and P2. With this arrangement, the amount of cooling fluid E delivered from cooling unit 126 to circulation condenser 124, and the amount of the liquid phase CL delivered from circulation condenser 124 to liquid supply manifold 116, can be controlled based on the vapor pressure in vapor return manifold 118. In one embodiment, for instance, if the vapor pressure measured by pressure sensor PS increases, meaning that more liquid is needed at cooling device 108, the speeds of pumps P1 and P2 can both be increased to provide more, and cooler, liquid phase CL to the liquid supply manifold 116 and to cooling device 108. Pressure sensor PS and its communicative coupling to pumps P1 and P2 can also be added to system 100, in which case systems 100 and 200 operate substantially the same way. In system 200, the circulation loop is the main cooling system because it functions as a localized high power density thermal management system in a fully two-phase immersion environment. The main cooling system can be also understood as the one that extracts a significant amount of the heat generated by the servers. For this reason, external cooling fluid E is first delivered to the circulation condenser through fluid line E2 before being delivered to the immersion condenser through fluid line E3.

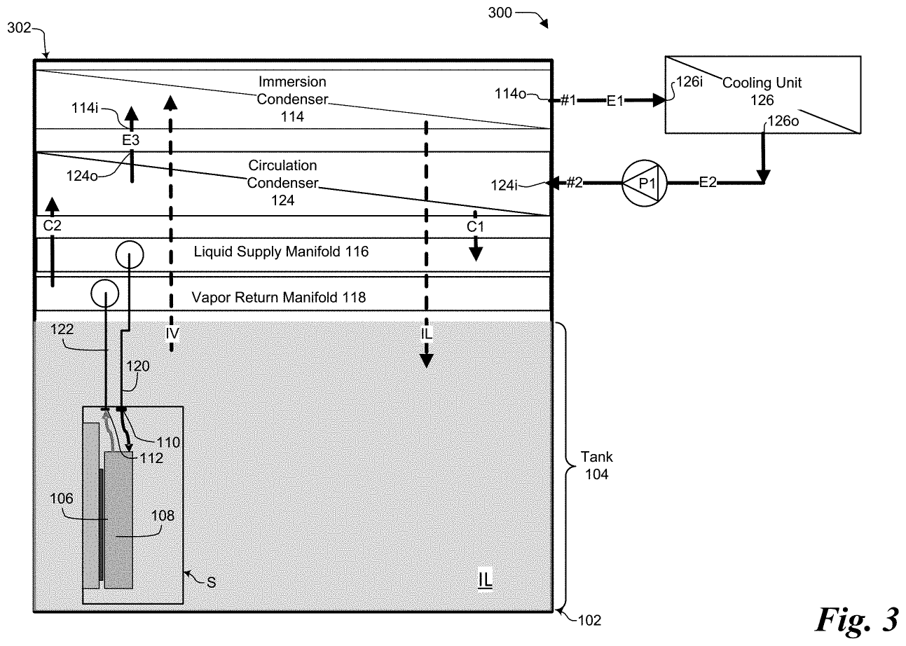

FIG. 3 illustrates another embodiment of a two-phase cooling system 300. System 300 is in many ways similar to system 100; the primary differences are the placement of some of the components and the operation of the system. Cooling system 300, like cooling system 100, combines global immersion cooling with local fluid circulation to cool heat-generating electronic components. Immersion cooling is accomplished using a two-phase immersion fluid I with a liquid phase IL and a vapor phase IV, while circulation cooling is accomplished using a two-phase circulation fluid C with a liquid phase CL and a vapor phase CV. Generally, immersion cooling fluid I will be a dielectric fluid, meaning that it has little or no electrical conductivity. In one embodiment, immersion cooling fluid I and circulation cooling fluid C are different two-phase fluids. In some embodiments, circulation fluid C will have a lower boiling point than immersion cooling fluid I, enabling it to absorb and carry away more heat. A third cooling fluid, external cooling fluid E, can be used to improve the transition from vapor phase to liquid phase for both cooling fluids I and C. The system is designed to minimize or prevent mixing of fluids I, C, and E.

Cooling system 300 includes an information technology (IT) container 302 with an internal volume that includes an immersion tank 104 adapted to hold the liquid phase IL of two-phase immersion cooling fluid I. In the illustrated embodiment immersion tank 104 is formed by a lower portion of the internal volume of IT container 202, but in other embodiments immersion tank 104 can be a physically separate tank within IT container 102. IT container 102 is sealed to reduce or prevent escape of liquid phase IL and, during operation, escape of vapor phase IV.

In the illustrated embodiment, one or more servers S are within the IT container 302. The illustrated embodiment includes one server S, but other embodiments can have more servers than shown. Within server S there are one or more heat-generating electronic components 106, and a cooling device 108 is thermally coupled to the heat-generating electronic component. Cooling device 108, which can be an evaporator in one embodiment, has a liquid inlet 110 and a vapor outlet 112. Server S is submerged in liquid phase IL, and to ensure immersion cooling the amount or level of liquid phase IL in immersion tank 104 is chosen so that the one or more servers S always remain fully submerged in the liquid phase.

Besides immersion tank 104, four main components are positioned above the tank in the interior volume of IT container 302: an immersion condenser 114, a circulation condenser 124, a liquid supply manifold 116, and a vapor return manifold 118. In system 300, then, circulation condenser 124 is positioned within the IT container, as opposed to system 100 in which it is positioned outside the IT container. Within IT container 302, immersion condenser 114 has an external inlet 114i fluidly coupled by physical fluid connection E3 to external outlet 124o of circulation condenser 124. Liquid supply manifold 116 is fluidly coupled by liquid line C1 to circulation condenser 124, and vapor return manifold 118 is also fluidly coupled by vapor line C2 to the circulation condenser, with liquid phase CL flowing through C1 and vapor phase CV flowing through C2. Liquid supply manifold 116 is also fluidly coupled to inlet 110 of cooling device 108 by a liquid line 120, and vapor return line 122 is fluidly coupled between vapor outlet 112 and vapor return manifold 118. As described below, cooling device 108, liquid supply manifold 116, vapor return manifold 118, and circulation condenser 124 form part of a two-phase circulation cooling loop to provide localized two-phase cooling to heat-generating component 106.

An external cooling unit 126, separate from IT container 302, is fluidly coupled to both immersion condenser 114 and circulation condenser 124 to circulate external cooling fluid E through both condensers, improving their ability to condense their respective two-phase fluids. External outlet 114o of immersion condenser 114 is fluidly coupled by fluid line E1 to inlet 126i of cooling unit 126, and outlet 126o of cooling unit 126 is fluidly coupled by fluid line E2 to external inlet 124i of circulation condenser 124. As described above, immersion condenser 114 has an external inlet 114i fluidly coupled by fluid connection E3 to external outlet 124o of circulation condenser 124, so that fluid lines E1-E3 form a loop through which fluid E flows. A pump P1 is coupled into fluid line E2 to boost the pressure and/or flow rate of cooling fluid E flowing into and through circulation condenser 124 and immersion condenser 114. In other embodiments P1 can instead be coupled into fluid line E3 or fluid line E1.

As in system 200, system 300 includes fluid interfaces to assist modularization. System 300 includes two fluid interfaces, but other embodiments can include more or less interfaces than shown. Fluid interfaces #1 and #2 are used to couple cooling unit 126 to the immersion condenser and the circulation condenser within IT container 302. The fluid interfaces are as follows:
Fluid interface #1 is fluidly coupled in fluid line E1 between external outlet 114o of immersion condenser unit 114 and external inlet 126i of the cooling unit. Fluid interface #1 is positioned in fluid line E1 between IT container 302 and cooling unit 126.
Fluid interface #2 is fluidly coupled in fluid line E2 between external outlet 126o of the cooling unit and external inlet 124i of circulation condenser 124. Fluid interface #2 is positioned in line E2 downstream of pump P1 between cooling unit 126 and IT container 302.

During operation of cooling system 300, heat-generating components within servers S are cooled by both the immersion cooling loop and the circulation cooling loop. In the immersion cooling loop, heat generated by heat-generating components 106 within servers S can be transferred to liquid phase IL of the immersion fluid I, transforming it by evaporation into vapor phase IV. Vapor phase IV rises into the space between a surface of the liquid phase IL in immersion tank 104 and the top of the IT container 202, where it enters immersion condenser 114 and condenses back into liquid phase IL. External cooling fluid E from cooling unit 126 flows through immersion condenser 114, as described above, to improve its condensation rate. By the force of gravity, liquid phase IL drops from immersion condenser 114 back into immersion tank 104, where it will again be transformed by heat into vapor phase IV, thus completing the immersion cooling loop.

The circulation cooling loop operates simultaneously with the immersion cooling loop to provide enhanced and more localized cooling to heat-generating components 106. The liquid phase CL of circulation cooling fluid C flows from liquid supply manifold 116, through liquid supply line 120 and liquid inlet 110, into cooling device 108. In cooling device 108 the liquid phase CL absorbs heat from heat-generating device 106 and is converted into vapor phase CV. Vapor phase CV then flows out of cooling device 108 through vapor outlet 112 and vapor line 122 to vapor return manifold 118. Vapor phase CV then flows from vapor return manifold 118 into circulation condenser 124 through vapor line C2. In circulation condenser 124, vapor phase CV, with the help of external cooling fluid E from cooling unit 126, condenses vapor phase CV back into liquid phase CL. Liquid phase CL is then returned by gravity from the circulation condenser to liquid supply a supply manifold 116 through liquid supply line C1, completing the circulation cooling loop. Thus, in system 300 the vapor phases CV and IV rise naturally to the condensers in their respective cooling loops and liquid phases IL and CL drop by gravity to the tank and the liquid supply manifold respectively.

In system 300 the circulation loop is the main cooling system because it functions as a localized high power density thermal management system in a fully two-phase immersion environment. For this reason, external cooling fluid E is first delivered to the circulation condenser through fluid line E2 before being delivered to the immersion condenser through fluid line E3.

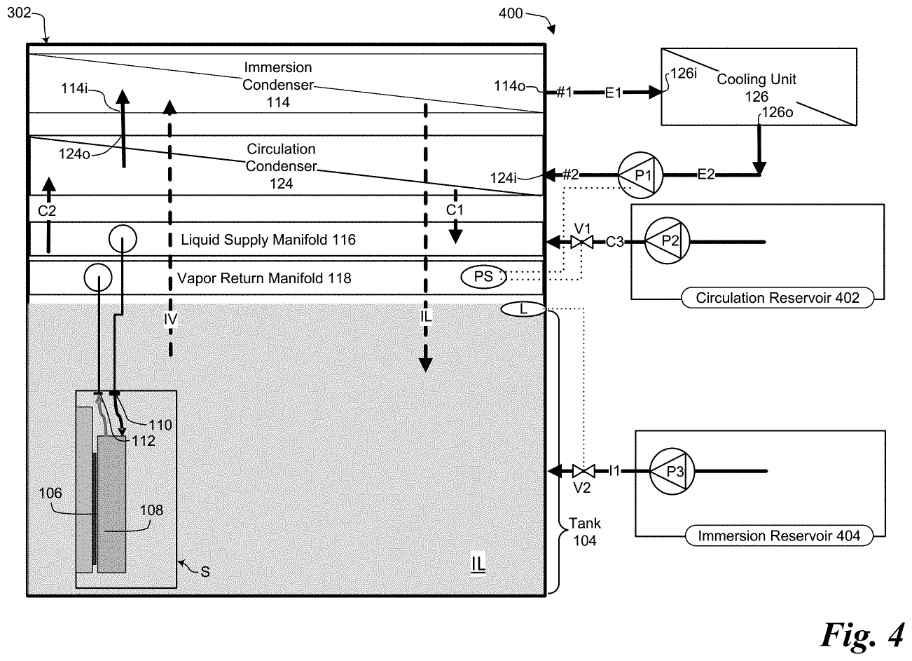

FIG. 4 illustrates another embodiment of a two-phase cooling system 400. Cooling system 400 is in most respects similar to cooling system 300. System 400 includes IT container 302 and cooling unit 126; both include the same components as in system 300, with the components within IT container 302 and cooling unit 126 fluidly connected in the same way. The primary difference between systems 300 and 400 is that system 400 includes additional fluid and control components to manage operation of the system. System 400, then, operates similarly to system 300, but with additional controls.

System 400 includes a pair of reservoirs to help manage the liquid phases of the immersion fluid and the circulation fluid. Circulation reservoir 402 holds the liquid phase CL of circulation fluid C and is fluidly coupled, by fluid line C3, to liquid supply manifold 116. A pump P2 is coupled into fluid line C3, and a control valve V1 is coupled into fluid line C3 downstream of pump P2. Similarly, immersion reservoir 404 holds the liquid phase IL of immersion fluid I and is fluidly coupled, by fluid line I1, to immersion tank 104. A pump P3 is coupled into fluid line I1, and a control valve V2 is coupled into fluid line I1 downstream of pump P3. In other embodiments circulation reservoir 402 and immersion reservoir 404 can be fluidly coupled to more than one IT container at a time, so that pumps P2 and P3 are also shared by more than one IT container.

A pressure sensor PS is positioned in vapor return manifold 118 and is communicatively coupled to pump P1 and control valve V1 so that the amount of circulation fluid flowing through the circulation loop can be controlled by controlling the pump speed and the open ratio of the valve. The open ratio of control valve V1 is a measure of how open the valve is. In one embodiment the open ratio can have any value between 0 and 1: an open ratio of 0 means the valve is fully closed and all flow is cut off; an open ratio of 1 means the valve is fully open and fluid flows freely through it; an open ratio of 0.5 means the valve is half open; and so on.

In operation, if the vapor pressure measured by pressure sensor PS drops, meaning that more liquid phase CL is needed at cooling device 108, the speed of pump P2 and the open ratio of control valve V1 can both be increased. An increase in the pump speed and valve open ratio results in liquid-phase fluid CL being delivered from the circulation reservoir into liquid supply manifold 116 at higher pressure and flow rate, thus delivering more liquid phase to cooling device 108. Put differently, pump P2 and control valve V1 are used in a combined manner to making up lost circulation flowing through fluid lines C2 and C2. In other embodiments, circulation reservoir 402 can be fluidly coupled to multiple IT containers 302, and individual control valves V1 of each IT container can provide individual control to that particular container.

IT container 302 cannot be perfectly sealed against exit of vapor phase IV, so the amount of liquid phase IL in immersion tank 104 naturally decreases over time and must occasionally be replenished. To accomplish this replenishment, a liquid level sensor L is positioned in immersion tank 104 and is communicatively coupled to control valve V2 so that the amount of immersion fluid in immersion tank 104 can be kept high enough that the one or more servers S are always kept fully submerged in the liquid phase IL of the immersion fluid. Liquid level sensor L can be used to control the open ratio of valve V2. If the level of liquid IL in immersion tank 104 drops below the required level, the open ratio of control valve V2 is increased, allowing liquid IL to flow into immersion tank 104 until the require liquid level is restored. Once the required liquid level is restored, the open ratio of control valve V2 is decreased to slow or stop the flow of liquid IL into the tank. Put differently, pump P3 and control valve V2 are used in a combined manner to making up lost liquid phase IL in tank 104. In other embodiments, immersion reservoir 404 can be fluidly coupled to multiple IT containers 302, and individual control valves V2 of each IT container can provide individual control to that particular IT container.

In system 400 the circulation loop is the main cooling system because it functions as a localized high power density thermal management system in a fully two-phase immersion environment. For this reason, external cooling fluid E is first delivered to the circulation condenser through fluid line E2 before being delivered to the immersion condenser through fluid line E3. In other embodiments, the control sensor can include more advanced ML algorithm for enhanced performance in different scenarios.

Other embodiments are possible besides the ones described above. For instance:
More advanced control and optimization algorithm can be integrated.
The IT container can be designed in different configurations.
The solution can be extended for more than two different types of two-phase immersion cooling fluid coexisting in one system.

The above description of embodiments is not intended to be exhaustive or to limit the invention to the described forms. Specific embodiments of, and examples for, the invention are described herein for illustrative purposes, but various modifications are possible.

What is claimed is:

1. An information technology (IT) cooling system comprising:
an IT container defining an internal volume, the internal volume having therein:
an immersion tank adapted to submerge one or more servers in a two-phase immersion fluid,
an immersion condenser positioned above the immersion tank in the internal volume, the immersion condenser including an external inlet and an external outlet, and
a liquid distribution manifold and a vapor return manifold positioned in the internal volume above the immersion tank and adapted to circulate a two-phase circulation fluid, the liquid distribution manifold being adapted to be fluidly coupled to a liquid inlet of a cooling device that is thermally coupled to a heat-generating electronic component in at least one of the one or more servers, and the vapor return manifold being adapted to be fluidly coupled to a vapor outlet of the cooling device.

2. The IT cooling system of claim 1, further comprising:
a circulation condenser external to the IT container and fluidly coupled to the liquid distribution manifold and the vapor return manifold, the circulation condenser including an external inlet and an external outlet; and
an external cooling unit fluidly coupled to the immersion condenser and the circulation condenser, wherein the external cooling unit is adapted to circulate an external cooling fluid through the immersion condenser and the circulation condenser.

3. The IT cooling system of claim 2 wherein the external cooling unit has an inlet and an outlet and forms an external cooling loop wherein:
the external outlet of the immersion condenser is fluidly coupled to the inlet of the external cooling unit;
the outlet of the external cooling unit is fluidly coupled to the external inlet of the circulation condenser; and
the external outlet of the circulation condenser is fluidly coupled to the external inlet of the immersion condenser.

4. The IT cooling system of claim 3, further comprising a first pump fluidly coupled in the external cooling loop for recirculating the external cooling fluid among the cooling unit, the immersion condenser, and the circulation condenser.

5. The IT cooling system of claim 4 wherein the circulation condenser, the first pump, and at least part of the fluid coupling between the external outlet of the immersion condenser and the inlet of the cooling unit are packaged together in a condenser unit external to the IT container.

6. The IT cooling system of claim 5 wherein the IT container and the condenser unit include fluid coupling interfaces through which the external cooling unit and the circulation condenser are fluidly coupled to the immersion condenser and through which the circulation condenser is fluidly coupled to the liquid distribution manifold and the vapor return manifold.

7. The IT cooling system of claim 4, further comprising a second pump coupled between the circulation condenser and the liquid distribution manifold.

8. The IT cooling system of claim 7 wherein the second pump is packaged within the IT container.

9. The IT cooling system of claim 4, further comprising a pressure sensor positioned in the vapor return manifold, the pressure sensor being communicatively coupled to the first pump.

10. The IT cooling system of claim 1 wherein the two-phase immersion fluid and the two-phase circulation fluid are different two-phase fluids.

11. A cooling system for an information technology (IT) enclosure, the cooling system comprising:
an IT container defining an internal volume, the internal volume having therein:
an immersion tank adapted to submerge one or more servers in a two-phase immersion fluid,
an immersion condenser positioned above the immersion tank in the internal volume, the immersion condenser including an external inlet and an external outlet,
a liquid distribution manifold and a vapor return manifold positioned above the immersion tank and adapted to transport a two-phase circulation fluid, the liquid distribution manifold being adapted to be fluidly coupled to a liquid inlet of a cooling device that is thermally coupled to a heat-generating electronic component in at least one of the one or more servers, and the vapor return manifold being adapted to be fluidly coupled to a vapor outlet of the cooling device, and
a circulation condenser positioned in the internal volume above the immersion tank, the circulation condenser being fluidly coupled to the liquid distribution manifold and the vapor return manifold, and the circulation condenser having an external outlet and an external inlet, the external outlet being coupled to the external inlet of the immersion condenser.

12. The IT cooling system of claim 11, further comprising an external cooling unit fluidly coupled to the external outlet of the immersion condenser and the external inlet of the circulation condenser to form an external cooling loop, wherein the external cooling unit is adapted to circulate an external cooling fluid through the immersion condenser and the circulation condenser.

13. The IT cooling system of claim 12, further comprising a first pump fluidly coupled into the external cooling loop to recirculate the external cooling fluid among the cooling unit, the immersion condenser, and the circulation condenser.

14. The IT cooling system of claim 13 wherein the external cooling unit includes fluid coupling interfaces through which the external cooling unit is fluidly coupled to the external outlet of the immersion condenser and the external inlet of the circulation condenser.

15. The IT cooling system of claim 12, further comprising a circulation reservoir for a liquid phase of the two-phase circulation fluid, the circulation reservoir being fluidly coupled by a first control valve to the liquid distribution manifold.

16. The IT cooling system of claim 15, further comprising a second pump fluidly coupled between the circulation reservoir and the first control valve.

17. The IT cooling system of claim 16, further comprising a pressure sensor positioned in the vapor return manifold, the pressure sensor being communicatively coupled to the first control valve and the second pump.

18. The IT cooling system of claim 12, further comprising an immersion reservoir for a liquid phase of the two-phase immersion fluid, the immersion reservoir being fluidly coupled by a second control valve to the immersion tank.

19. The IT cooling system of claim 18, further comprising a third pump fluidly coupled between the immersion reservoir and the second control valve.

20. The IT cooling system of claim 19, further comprising a liquid level sensor positioned in the tank, the liquid level sensor being communicatively coupled to the second control valve and the third pump.
